(19) United States
(12) Patent Application Publication
(10) Pub. No.: US 2026/0160838 A1
(43) Pub. Date: Jun. 11, 2026

(54) MAGNETIC RESONANCE SYSTEM AND SCANNING METHOD FOR MAGNETIC RESONANCE SYSTEM

(71) Applicant: GE Precision Healthcare LLC, Waukesha, WI (US)

(72) Inventors: Yanchun Zheng, Beijing (CN); Kun Wang, Beijing (CN); Xuelian Lu, Beijing (CN); Jiabin Yao, Beijing (CN); Cunli Zhang, Beijing (CN)

(21) Appl. No.: 19/415,719

(22) Filed: Dec. 10, 2025

(30) Foreign Application Priority Data
Dec. 11, 2024 (CN) 202411822641.5

(51) Int. Cl. G01R 33/36; G01R 33/54

(52) U.S. Cl. CPC G01R 33/3692; G01R 33/546

(57) ABSTRACT

A magnetic resonance system and a scanning method for a magnetic resonance system are provided. The method includes: acquiring a type of a radio frequency coupling coil; and on the basis of the type of the radio frequency coupling coil, determining a parameter for performing a magnetic resonance scan on a subject to be examined; the radio frequency coupling coil is positioned relative to the subject to be examined, and when positioned within a body coil of the magnetic resonance system, the radio frequency coupling coil is configured to generate electromagnetic coupling with the body coil to receive a radio frequency pulse from the body coil, so as to generate a radio frequency field for exciting the subject to be examined.

### CROSS REFERENCE TO RELATED APPLICATIONS

The present application claims priority and benefit of Chinese Patent Application No. 202411822641.5 filed on Dec. 11, 2024, which is incorporated herein by reference in its entirety.

### TECHNICAL FIELD

Embodiments of the present application relate to the technical field of medical imaging, and relate in particular to a magnetic resonance system and a scanning method for a magnetic resonance system.

### BACKGROUND

Magnetic resonance systems have been widely used in the field of medical diagnosis. Existing magnetic resonance systems generally have a main magnet, a radio frequency coil, a gradient coil, and the like. The radio frequency coil transmits a radio frequency excitation signal for exciting a scanned subject to generate a magnetic resonance signal, based on which a medical image of the scanned subject can be reconstructed.

Currently, the radio frequency coil includes a transmit coil and a receive coil, or a transmit/receive coil (which may be used to transmit a radio frequency pulse and receive a magnetic resonance signal). The transmit/receive coil includes, for example, a body coil, which is disposed along a scanning cavity to surround the scanned subject. The body coil is capable of receiving a radio frequency power signal from a radio frequency transmit link to generate a radio frequency excitation pulse for exciting the whole body of the scanned subject, and is therefore suitable for whole body imaging.

The transmit coil or the transmit/receive coil may further include a local coil. When a medical image of a local body part needs to be obtained, a corresponding local coil may be used to obtain better image quality. The local coil includes, for example, a head coil, a knee coil, a shoulder coil, a spine coil, and a wrist coil.

Generally, when the local coil is used, the local coil needs to be connected to the radio frequency transmit link through a cable port (for example, disposed on a scanning table), and an output of the radio frequency transmit link may be selected to be coupled to the body coil or the local coil by means of a switching switch. When the local coil is selected, the body coil does not work.

When performing a magnetic resonance scan on a subject to be examined, a corresponding scan protocol may be selected and executed on the basis of a currently selected coil (e.g., the body coil or the local coil).

### SUMMARY OF THE INVENTION

The inventors of the present application have found that a radio frequency coupling coil having a smaller volume than the body coil can be used to perform magnetic resonance imaging, and the radio frequency coupling coil can be coupled to a local part of a subject; and the radio frequency coupling coil does not need to be connected to a magnetic resonance system in a wired manner, but receives, through wireless electromagnetic coupling with the body coil, a radio frequency pulse transmitted by the body coil, so as to generate a radio frequency field for exciting the local part.

The inventors have further found that when the radio frequency coupling coil is used to perform a magnetic resonance scan on a subject to be examined, there are challenges in quickly setting appropriate scanning parameters. For example, when the radio frequency coupling coil is used, the body coil is in a working state. However, scanning parameters obtained by a parameter determination method based on the body coil may not be appropriate for the radio frequency coupling coil, resulting in the inability to obtain scan images that meet clinical needs; or a large amount of time may be required to determine the final scanning parameters, which increases the scanning time and reduces the scanning efficiency.

To solve the above technical problem or at least similar technical problems, embodiments of the present application provide a magnetic resonance system and a scanning method for a magnetic resonance system. In this method, a type of a radio frequency coupling coil is determined, and a parameter for a magnetic resonance scan is determined on the basis of the type, thereby automatically setting appropriate scanning parameters for different radio frequency coupling coils to ensure the image quality and improve the scanning efficiency.

According to an aspect of the embodiments of the present application, a scanning method for a magnetic resonance system is provided. The scanning method comprises:
acquiring a type of a radio frequency coupling coil, and on the basis of the type of the radio frequency coupling coil, determining a parameter for performing a magnetic resonance scan on a subject to be examined. The radio frequency coupling coil is positioned relative to the subject to be examined, and when positioned within a body coil of the magnetic resonance system, the radio frequency coupling coil is configured to generate electromagnetic coupling with the body coil to receive a radio frequency pulse from the body coil, so as to generate a radio frequency field for exciting the subject to be examined.

According to an aspect of the embodiments of the present application, there is provided a magnetic resonance imaging system, the system comprising: a scanning table configured to carry a subject to be examined; a body coil configured to transmit radio-frequency pulses; and a radio-frequency coupling coil positioned relative to the subject. When the radio-frequency coupling coil is located within the body coil, it is configured to electromagnetically couple with the body coil to receive the radio-frequency pulses and generate a radio-frequency field for exciting the subject. The system further includes a processor configured to execute the magnetic resonance imaging method described herein

With reference to the following description and drawings, specific implementations of the embodiments of the present application are disclosed in detail, and the way in which the principles of the embodiments of the present application can be employed are illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to embodiments of the present application;

FIG. 2 is a flowchart of a scanning method for a magnetic resonance system according to some embodiments of the present application;

FIG. 3 is a flowchart of a scanning method for a magnetic resonance system according to some other embodiments of the present application;

FIG. 4 is a schematic diagram of a scanning table traveling from an initial position to a current position;

FIG. 5 is a flowchart of a scanning method for a magnetic resonance system according to some other embodiments of the present application;

FIG. 6 and FIG. 7 show a first example and a second example of a probability density model according to embodiments of the present application, respectively;

FIG. 8 and FIG. 9 show distribution models of critical anatomical sites according to some embodiments of the present application;

FIG. 10 is a flowchart of a scanning method for a magnetic resonance system according to some other embodiments of the present application;

FIG. 11 is a flowchart of a scanning method for a magnetic resonance system according to some other embodiments of the present application;

FIG. 12 is a flowchart of a scanning method for a magnetic resonance system according to some other embodiments of the present application;

FIG. 13 is a flowchart of estimating a type of a radio frequency coupling coil in some embodiments of the present application;

FIG. 14 shows exemplary diagrams of user interfaces displaying estimation results in some embodiments of the present application;

FIG. 15 is a flowchart of a scanning method for a magnetic resonance system according to some other embodiments of the present application;

FIG. 16 is a schematic structural diagram of a body coil and a radio frequency coupling coil according to some embodiments of the present application;

FIG. 17 is a schematic structural diagram of a radio frequency coupling coil according to some other embodiments of the present application; and

FIG. 18 is a schematic structural diagram of the radio frequency coupling coil in FIG. 17 in an expanded and disassembled state.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc. are used to distinguish between different elements in terms of appellation, but do not represent a spatial arrangement, a temporal order, or the like of these elements, and these elements should not be limited by these terms. The term “and/or” includes any one of and all combinations of one or more associated listed terms. The terms “include”, “comprise”, “have”, etc. refer to the presence of described features, elements, components, or assemblies, but do not exclude the presence or addition of one or more other features, elements, components, or assemblies.

In the embodiments of the present application, the singular forms “a” and “the”, etc., include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ” and the term “based on” should be construed as “based at least in part on . . . ”, unless otherwise specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

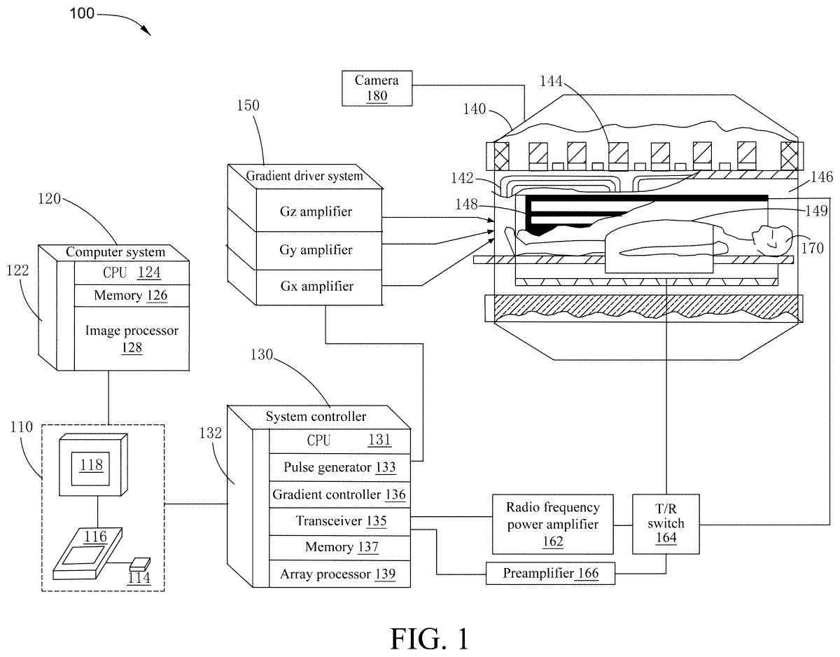

For ease of understanding, FIG. 1 shows a magnetic resonance system 100 according to some embodiments of the present invention.

The operation of the magnetic resonance system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118.

The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate system controller 130.

The system controller 130 includes a set of components that communicate with one another by means of an electrical and/or data connection module 132. The connection module 132 may employ a direct wired connection, a fiber optic connection, a wireless communication link, etc. The system controller 130 may include a CPU 131, a pulse generator 133 that communicates with the operator workstation 110, a transceiver (or an RF transceiver) 135, a gradient controller 136, a memory 137, and an array processor 139. In some embodiments, the pulse generator 133 may be integrated into a resonance assembly 140 of the magnetic resonance system 100.

A subject (or a subject or patient to be examined) 170 to be subjected to a magnetic resonance scan may be positioned within a cylindrical imaging volume (or a scanning cavity) 146 of the resonance assembly 140 by means of a scanning table. The system controller 130 controls the scanning table to travel in a Z-axis direction of the magnetic resonance system, so as to deliver a predetermined site to be scanned of the subject 170 to a scanning region in the imaging volume 146, for example, being aligned with a scan center of the magnetic resonance system.

A camera 180 may be disposed on the magnetic resonance system or within a scan room in which the magnetic resonance system is located. The system controller 130 may control the camera 180 to acquire optical images. In some embodiments, one or more scanning operations or magnetic resonance image processing may be implemented by analysis, operation, etc. based on the optical images.

The system controller 130 may receive a command from the operator workstation 110 to indicate a scan sequence that is to be executed during a magnetic resonance scan performed on the scanned subject 170. The “scan sequence” above refers to a combination of pulses that have specific intensities, shapes, timings, and the like and that are applied when a magnetic resonance scan is performed. The pulses may typically include, for example, a radio frequency pulse and a gradient pulse. A plurality of scan sequences may be pre-stored in the computer system 120, so that a sequence suitable for clinical examination requirements can be indicated by means of the operator workstation. The clinical examination requirements may include, for example, an imaging site, an imaging function, an imaging effect, scanning safety, and the like. The system controller 130 operates, on the basis of an instruction describing the timings, intensities, and shapes of a radio frequency pulse and a gradient pulse in the indicated sequence, a system component that executes the sequence.

A radio frequency pulse in the scan sequence sent by the pulse generator 133 may be generated by the transceiver 135, and the radio frequency pulse is amplified by a radio frequency power amplifier 162. The amplified radio frequency pulse is provided to the radio frequency transmit coil, such as the body coil 148 by means of a transmit/receive switch (T/R switch) 164, and the radio frequency transmit coil then immediately provides a transverse magnetic field B1. As a non-limiting example, a transmitting portion of the transceiver 135, the radio frequency power amplifier 162, the T/R switch 164, and the like constitute at least a portion of a radio frequency transmit link. The transverse magnetic field B1 is substantially perpendicular to B0 throughout the cylindrical imaging volume 146, and the transverse magnetic field B1 is used to excite stimulated nuclei within the body of the scanned subject 170, thereby generating a magnetic resonance signal. The system controller 130 further provides gradient waveforms to a gradient driver

system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in a gradient coil assembly 142, so as to generate a magnetic field gradient for spatially encoding a magnetic resonance signal during a magnetic resonance scan. The gradient coil assembly 142 is disposed within the resonance assembly 140. The x direction may also be referred to as a frequency encoding direction or a kx direction in K-space. The y direction may be referred to as a phase encoding direction or a ky direction in the K-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The resonance assembly 140 further includes a superconducting magnet having a superconducting coil 144 that, in operation, provides a static uniform longitudinal magnetic field B0 throughout the cylindrical imaging volume 146.

The resonance assembly 140 further includes a body coil 148, which may be configured to receive a radio frequency power signal from the radio frequency transmit link to transmit a radio frequency pulse, and in operation thereof in the transmit mode, provide a transverse magnetic field B₁, the transverse magnetic field B₁ being substantially perpendicular to B₀ throughout the cylindrical imaging volume 146.The body coil 148 may be further configured to receive a magnetic resonance signal from the scanned subject. The body coil 148 may be configured by the transmit/receive switch (T/R switch) 164 to operate in the transmit mode or the receive mode. Specifically, the T/R switch 164 may be controlled by a signal from the system controller 130 to electrically connect, during the transmit mode, the radio frequency power amplifier 162 to the RF body coil 148 and to connect, during the receive mode, the preamplifier 166 to the RF body coil 148.

A radio frequency local coil (or surface coil) 149 may be further provided, and the body coil, the radio frequency local coil, or the surface coil may be employed to receive a magnetic resonance signal generated by the scanned subject. The magnetic resonance signal may be sent back to the preamplifier 166 through the T/R switch 164.

In some embodiments, the magnetic resonance signal sensed and received by the coil and amplified by the preamplifier 166 is demodulated, filtered, and digitized in a receiving portion of the transceiver 135, and transmitted to the memory 137 in the system controller 130. For each image that is to be reconstructed, the data is rearranged into a separate k-space data array, each of the separate k-space data arrays is inputted into the array processor 139, and the array processor is operated to transform the data into an array of image data by means of a Fourier transform.

The array processor 139 uses a transform method, which is most commonly Fourier transform, to reconstruct images from the received magnetic resonance signal. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the system controller 130 may be implemented on the same computer system or on a plurality of computer systems. The system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, image processing, etc. For example, the storage medium may store a program used to implement the magnetic resonance imaging method according to the embodiments of the present invention. The above storage medium may include, for example, a ROM, a floppy disk, a hard disk, an optical disk, a magneto-optical disk, a CD-ROM, or a non-volatile memory card.

It should be understood that the magnetic resonance system 100 shown in FIG. 1 is intended for illustration. A suitable magnetic resonance system may include more, fewer, and/or different components.

As described above, the body coil 148 may be configured to transmit a radio frequency pulse and to receive a magnetic resonance signal, although in general a local coil may also be employed to transmit a radio frequency pulse and to receive a magnetic resonance signal. The local coil includes, for example, a knee coil, a shoulder coil, a spine coil, a wrist coil, and a head and neck coil. The local coil is typically positioned close to the patient and thus provides a higher signal-to-noise ratio (SNR).

Currently, common local coils adopt a phased array coil composed of a plurality of coil elements. Each type of local coil needs to be equipped with its own corresponding cable and receiving channel for transmission of magnetic resonance signals. The local coil is connected to a radio frequency receive link via a cable interface disposed on a scanning table. A magnetic resonance signal received from the local coil are transmitted to the radio frequency receive link through the cable, amplified by a radio frequency preamplifier, and then demodulated, filtered, analog-to-digital converted, pre-processed, and Fourier transformed, etc., and finally reconstructed into a magnetic resonance image.

The phased array coil typically includes a decoupling circuit. In some embodiments, the decoupling circuit may be used for electromagnetic decoupling with the radio frequency transmit coil during radio frequency transmission to avoid affecting the transmit field.

The inventors have also found that a decoupling circuit included in the phased array coil requires DC power to operate, so the coil array also needs to rely on cables for DC power supply, but this increases the difficulty in wiring. In addition, to improve the image quality, the number of receive channels is increasing. For example, the number of receive channels is 16 or 32 or 64 or the like, which undoubtedly further increases the complexity of the cable interface and the cable and increases costs.

Although some local coils are also capable of transmitting a radio frequency excitation signal and receiving a magnetic resonance signal (self-transmission and self-reception), in addition to requiring the receive cable, the receive channel, and the decoupling circuit described above, the local coils further need to be electrically connected to the radio frequency transmit link to receive a radio frequency excitation pulse from the radio frequency transmit link. This also increases the difficulty in wiring. In addition, the electrical structure of such a local coil is typically disposed on a hard material.

The embodiments of the present application relate to a radio frequency coupling coil for a magnetic resonance imaging system. The radio frequency coupling coil is configured to cooperate with a site to be scanned of a subject to be examined (for example, the subject 170), and is coupled in the magnetic resonance system in a wireless cable connection manner. The radio frequency coupling coil may be positioned relative to the subject to be examined. For example, the radio frequency coupling coil may be configured to wrap around/surround/cover/be placed in close proximity to a site to be scanned of the subject to be examined. The site to be scanned includes a partial body part of the subject, such as a shoulder, a head, a knee, a limb, an ankle joint, a wrist joint, etc. During a scan, the radio frequency coupling coil is configured to couple to a body coil (for example, the body coil 148 in FIG. 1) of the magnetic resonance system (for example, it is positioned within the radio frequency body coil of the magnetic resonance system) to receive a radio frequency pulse transmitted from the body coil, so as to generate a radio frequency field for exciting the subject 170, thereby exciting the subject 170 to generate a magnetic resonance signal. In addition, the radio frequency coupling coil is further configured to send, to the body coil, a magnetic resonance signal received from the subject 170. In this way, a magnetic resonance scan of the subject 170 is implemented.

The body coil may be a quadrature coil, but the embodiments of the present application are not limited thereto. Those skilled in the art understand that the quadrature coil is also a birdcage-like coil. For implementations of the quadrature coil, reference may be made to related technologies, and details are not described herein.

In some embodiments, the radio frequency coupling coil is a flexible coil that at least partially surrounds at least one body part of the subject to be examined, wherein the at least one body part includes a site to be scanned of the subject to be examined. During a scan, the scanning table is controlled to move to position the site to be scanned of the subject and the radio frequency coupling coil in the scanning space defined by the body coil. In this case, the radio frequency coupling coil is located between the body coil and the subject, and the radio frequency local coil is closer to the subject to be examined than the body coil.

Some operations in a conventional magnetic resonance scanning procedure are not applicable to the radio frequency coupling coil. For example, the use of the radio frequency coupling coil brings challenges to parameter settings of the magnetic resonance scan. Specifically, taking a transmit gain (TG) as an example, in the conventional magnetic resonance scanning procedure, at a pre-scanning stage, it is necessary to determine a radio frequency power signal that meets a pulse sequence requirement, and the radio frequency transmission link provides a plurality of radio frequency power signals. The plurality of radio frequency power signals have different TG values, so that a plurality of radio frequency excitation pulses generated by the body coil have different flip angles, respectively. The flip angle changes with the change of the TG value. A TG value (for example, a flip angle of 20 degrees) that meets a flip angle requirement of a current pulse sequence can be deduced on the basis of one of the TG values (for example, a specific TG value corresponding to a flip angle of 90 degrees) and the change trend of the flip angle. However, the radio frequency coupling coil has an amplification effect on the radio frequency field generated by the body coil, so that the TG value estimated on the basis of the above method cannot generate a required flip angle. For example, the flip angle corresponding to the specific TG value may no longer be a flip angle of 90 degrees, thereby making it difficult to deduce the TG value corresponding to the required flip angle.

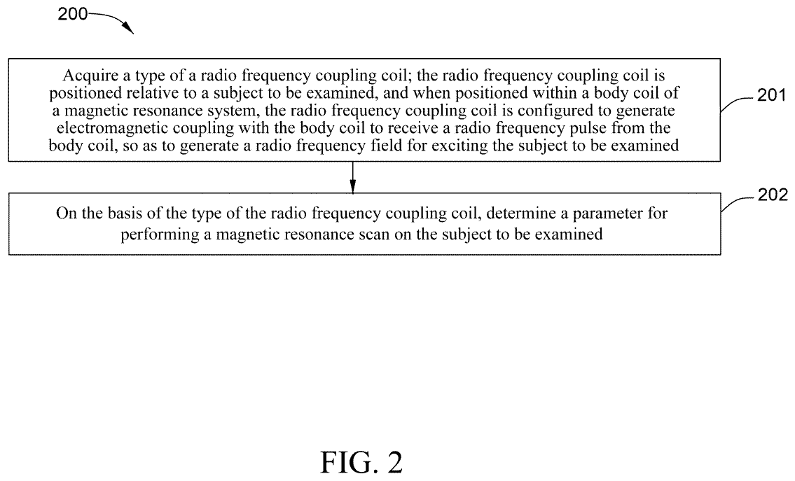

FIG. 2 is a flowchart 200 of a scanning method for a magnetic resonance system according to some embodiments of the present application. In step 201, a type of a radio frequency coupling coil is acquired, and in step 202, a parameter for performing a magnetic resonance scan on a subject to be examined is determined on the basis of the type of the radio frequency coupling coil. As described above, the radio frequency coupling coil is positioned relative to the subject to be examined, and when positioned within a body coil of the magnetic resonance system, the radio frequency coupling coil is configured to generate electromagnetic coupling with the body coil to receive a radio frequency pulse from the body coil, so as to generate a radio frequency field for exciting the subject to be examined.

It will be understood by those skilled in the art that different types of radio frequency coupling coils are used to image different body parts, that is, they are positioned relative to different body parts of the subject to be examined. For example, the above types of radio frequency coupling coils may include a head coil, a shoulder coil, a chest coil, an elbow coil, an abdomen coil, a wrist coil, a pelvis coil, a long bone coil (or a leg coil), a knee coil, a foot coil, etc.

By determining the parameter of the magnetic resonance scan on the basis of the type of the radio frequency coupling coil, a parameter determined on the basis of the body coil is prevent from being directly used to reduce imaging errors, so that an image obtained on the basis of the radio frequency coupling coil meets clinical requirements.

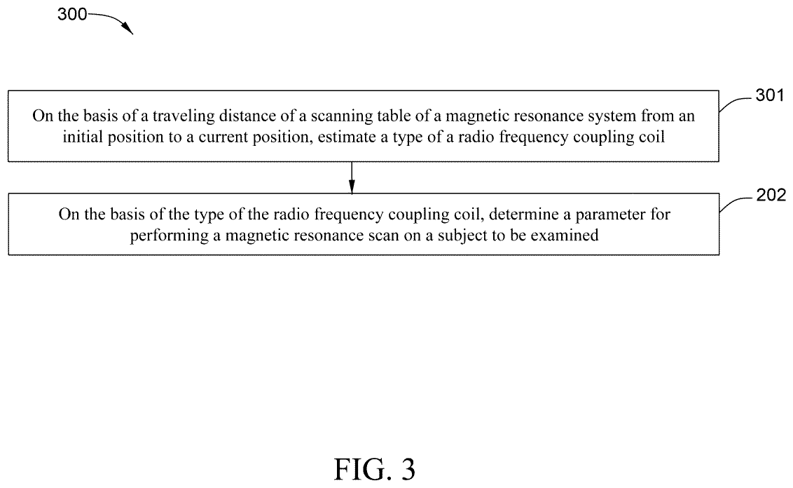

FIG. 3 is a flowchart 300 of a scanning method for a magnetic resonance system according to some other embodiments of the present application, wherein a type of a radio frequency coupling coil is determined on the basis of position feedback of a scanning table. Specifically, in step 301, the type of the radio frequency coupling coil is estimated on the basis of a traveling distance of the scanning table of the magnetic resonance system from an initial position to a current position.

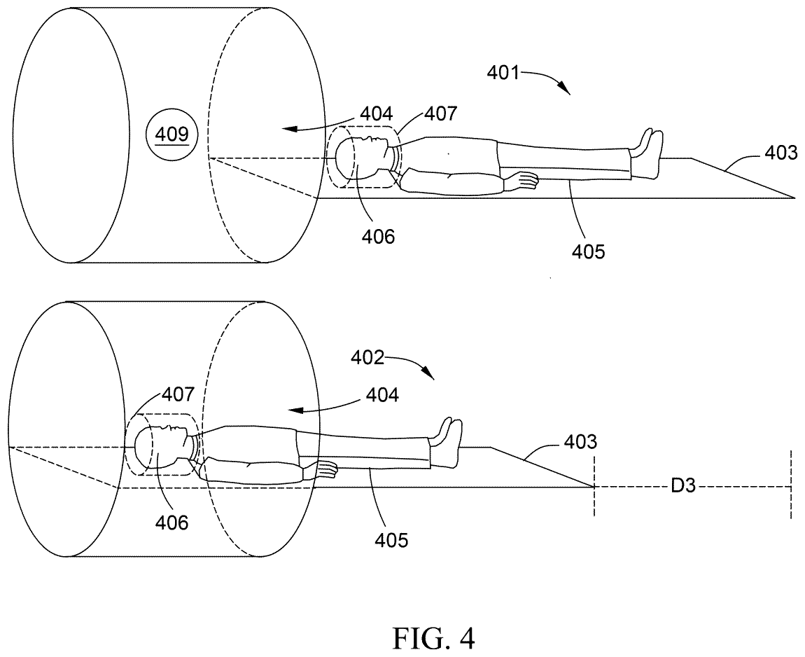

FIG. 4 is a schematic diagram of the scanning table traveling from the initial position to the current position. The initial position 401 may be a position of the scanning table 403 when the scanning table 403 does not enter a scanning cavity 404 (for example, a cylindrical scanning space formed by a main magnet), namely, a default position of the scanning table 403 when the magnetic resonance system is not working. The current position 402 may be a positioning position of the scanning table 403 after the scanning table 403 enters the scanning cavity 404, namely, a position of the scanning table 403 when the scanning table 403 travels from the outside of the scanning cavity 404 to the inside of the scanning cavity 404 and a site to be scanned 406 of a subject to be examined 405 being carried and a radio frequency coupling coil 407 disposed at the site to be scanned 406 are positioned in a scanning region. The scanning region may be a region in the scanning cavity 404 where the magnetic field is relatively uniform, for example, a region corresponding to a scanning center 409.

In step 301, according to the traveling distance D3 of the scanning table 403 from the initial position 401 to the current position 402, it can be determined which body part of the subject to be examined 405 may be located in the scanning region currently. For example, if a plurality of value intervals are set according to the distance, when the above traveling distance D3 falls within a first value interval with the smallest value, it can be determined that the site to be scanned of the subject to be examined 405 is a site close to an end portion of the scanning table 403 (for example, the head in a first body orientation or the foot in a second body orientation). If the traveling distance D3 is within a second value interval having values which are greater than those of the first value interval, it can be determined that the scanning table 403 has moved by a shorter distance, and it can be further determined that the site to be scanned of the subject to be examined 405 is a body part located between an end portion and the middle portion of the scanning table. If the traveling distance D3 is within a third value interval having values which are greater than those of the second value interval, it can be determined that the site to be scanned of the subject to be examined is a body part (for example, the abdomen) located in the middle portion of the scanning table 403. More value intervals may be set for the traveling distance according to actual conditions, so as to perform more accurate estimation. On the basis of the estimated site to be scanned, the type of the radio frequency coupling coil used in the current scan may be estimated accordingly.

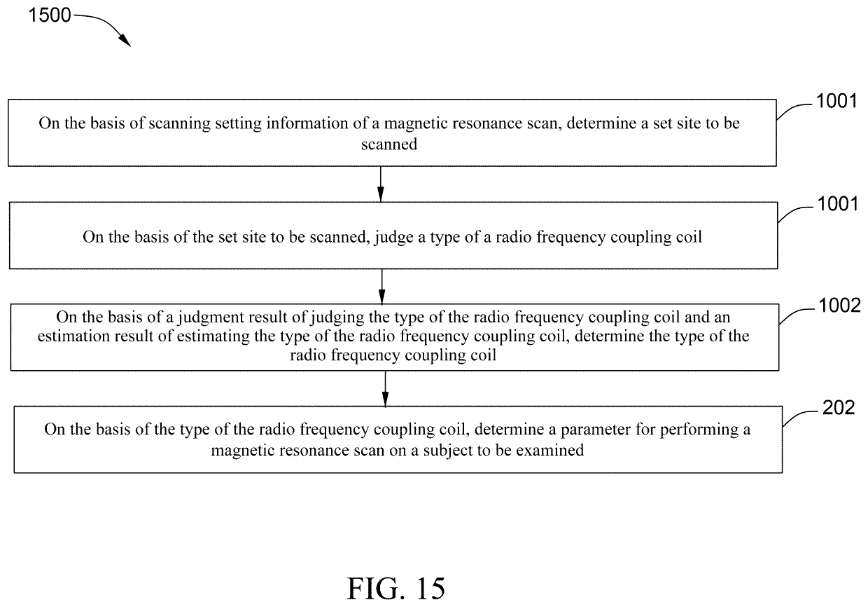

The estimation result of the type of the radio frequency coupling coil may be unique or non-unique, which depends on whether a body orientation of the subject to be examined is obtained in advance. For example, when the subject to be examined is in a first body orientation, the head is located at the end portion of the scanning table close to the scanning cavity, and the head first enters the scanning cavity along with the scanning table when performing a scan; and when the subject to be examined is in a second body orientation, the foot of the subject to be examined is located at the end portion of the scanning table close to the scanning cavity, and the foot first enters the scanning cavity along with the scanning table when performing a scan. In another aspect, whether the above estimation result is unique also depends on whether the same traveling distance corresponds to one or more body parts. For example, the abdomen and elbow of the subject to be examined are approximately at the same or similar coordinates in the length direction of the scanning table, so that when the scanning table travels to a corresponding position, both the abdomen and elbow are located at the scanning center. In another aspect, whether the above estimation result is unique also depends on whether other means are used to judge/determine the type of the radio frequency coupling coil. For example, as will be described below with reference to FIG. 15, a site to be scanned may also be determined on the basis of a set scan protocol retrieved, and the type of the radio frequency coupling coil used is judged on the basis of the determined site to be scanned.

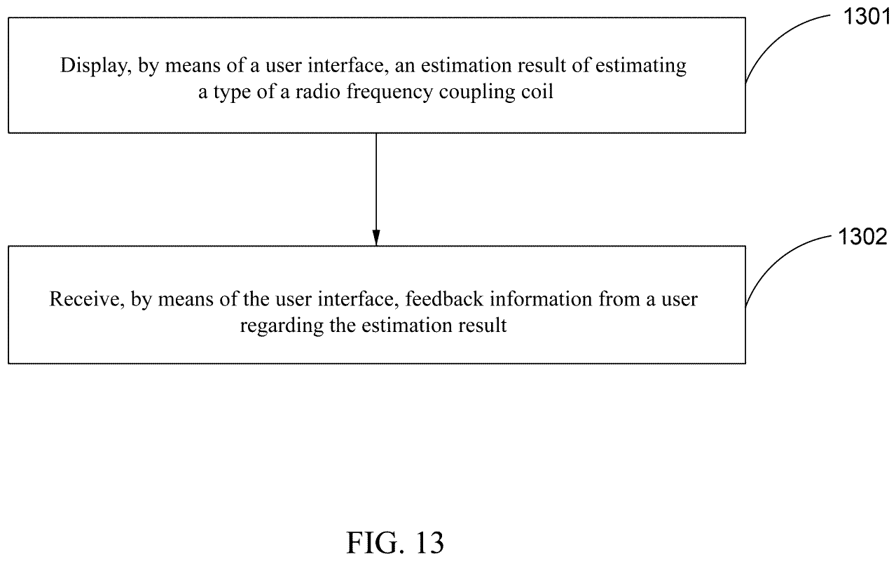

When the estimation result is unique, a parameter of a magnetic resonance scan may be determined on the basis of the unique result. When the estimation result is not unique, one type may be selected by a user from among a plurality of results to determine the parameter of the magnetic resonance scan on the basis of the selected type. When the type of the radio frequency coupling coil is further judged by other means, the type of the radio frequency coupling coil may also be confirmed or selected by the user from the estimation result and the judgment result. Details will be described below with reference to FIGS. 13 to 15.

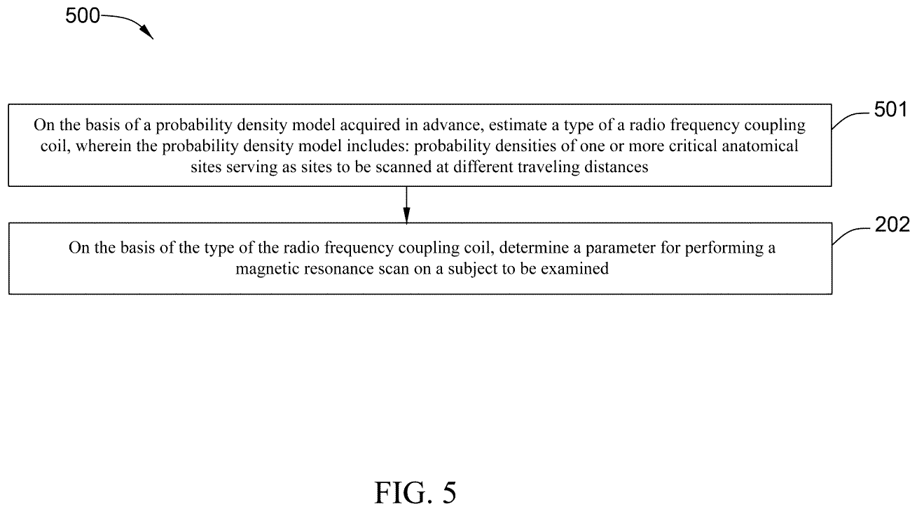

FIG. 5 is a flowchart 500 of a scanning method for a magnetic resonance system according to some other embodiments of the present application. In step 501, a type of a radio frequency coupling coil is estimated on the basis of a probability density model acquired in advance, wherein the probability density model includes: probability densities of one or more critical anatomical sites serving as sites to be scanned at different traveling distances.

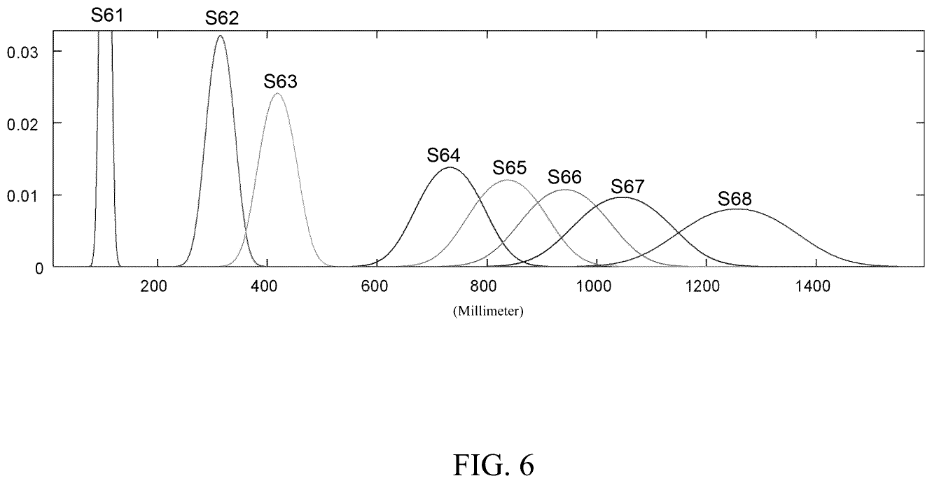

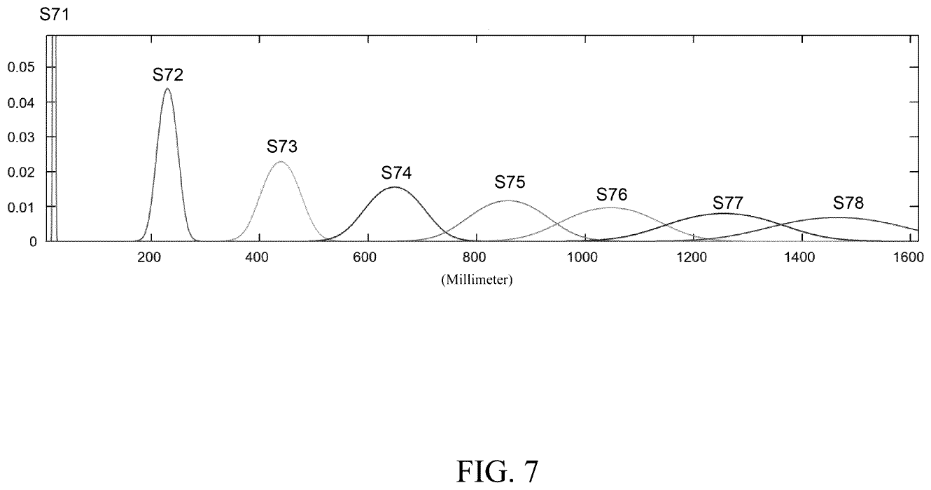

FIG. 6 and FIG. 7 respectively show a first example and a second example of a probability density model according to embodiments of the present application. The probability density curve of the first example may be obtained by analyzing a plurality of subjects to be examined in a first body orientation when being subjected to a magnetic resonance scan, and the probability density curve of the second example may be obtained by analyzing a plurality of subjects to be examined in a second body orientation when being subjected to a magnetic resonance scan. In FIG. 6 and FIG. 7, a probability density distribution model is represented by a curve. Specifically, the horizontal axis represents the above traveling distance D3 of the scanning table, and the vertical axis represents a probability density of a body part (or a critical anatomical site) serving as the site to be scanned. It will be understood by those skilled in the art that the model may also be represented in other forms.

Taking the model shown in FIG. 6 as an example for illustration, when the subject to be examined is in the first body orientation and the traveling distance D3 of the scanning table is within the value region where the curve S61 is located, it can be estimated that the site to be scanned is the head, and the type of the radio frequency coupling coil is a head coil. Similarly, when the traveling distance D3 of the scanning table is separately within the value ranges of the curves S62, S63, S64, S65, S66, S67, and S68, the type of the radio frequency coupling coil may be estimated as a shoulder coil, a chest coil, an abdomen or elbow coil, a pelvis coil, a buttock or wrist coil, a long bone coil, and a knee coil, respectively. Taking the model shown in FIG. 7 as an example again, when the subject to be examined is in the second body orientation and the traveling distance D3 of the scanning table is within the value interval of the curve S71, it can be estimated that the site to be scanned is the foot, and the type of the radio frequency coupling coil is a foot coil. Similarly, the traveling distance D3 of the scanning table is separately within the ranges of the curves S72, S73, S74, S75, S76, S77, and S78, and the type of the radio frequency coupling coil may be estimated as a leg coil, a knee coil, a long bone coil, a buttock or wrist coil, a pelvis coil, an abdomen or elbow coil, and a chest coil, respectively.

In some embodiments, when the traveling distance of the scanning table corresponds to a plurality of critical anatomical sites, for example, as shown in FIG. 6, when the traveling distance is within the value interval of 600 to 800 millimeters, both curves S4 and S5 are distributed therein. During estimation, a curve with a larger probability density value, for example, curve S4, is selected, and on the basis of this, it can be estimated that the type of the radio frequency coupling coil is an abdominal coil or an elbow coil. For another example, when the traveling distance is 1000 millimeters, the traveling distance corresponds to both regions S6 and S7, the estimation result is not unique and can be finally confirmed by the user.

It should be noted that, when assisting the positioning of the subject to be examined on the scanning table, the positioning position of the head of the subject to be examined on the scanning table may be indicated to guide each subject to be examined to position his head at this position, which is helpful to improve the accuracy of estimation.

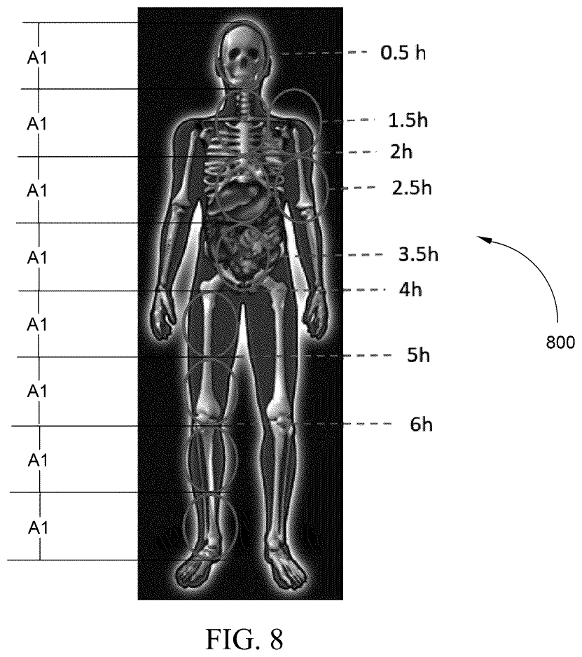

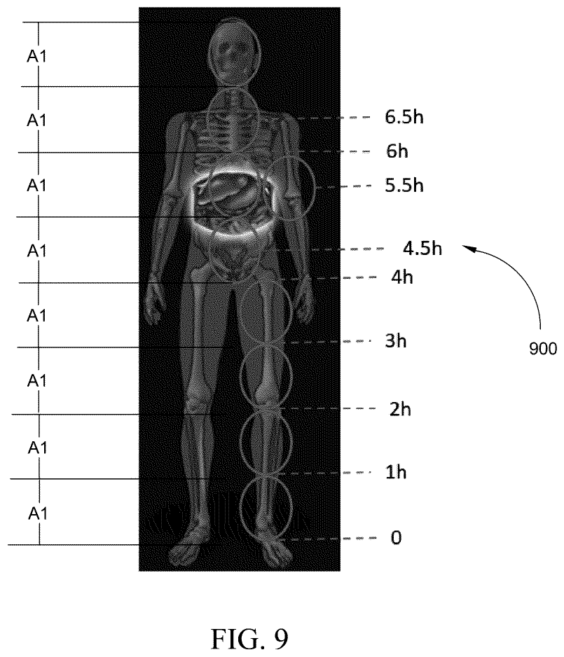

In the embodiments of the present application, the probability density may be obtained by statistics. Specifically, the probability density may be obtained by statistics on scanning information of a plurality of subjects to be examined, the plurality of subjects to be examined having different physiological characteristics. The probability density model may also be obtained on the basis of a distribution model of critical anatomical sites of a human body, which will be described below with reference to FIGS. 8 and 9. Moreover, the probability density model obtained on the basis of any of the above manners may be optimized through actual scanning information at a later stage, for example, through the traveling distance of the scanning table corresponding to the actual scanned site in the magnetic resonance scan.

FIG. 8 and FIG. 9 respectively show distribution models 800 and 900 of critical anatomical sites according to some embodiments of the present application. The distribution models may include position information of a plurality of critical anatomical sites in the whole body. Specifically, the site distribution models 800 and 900 include a plurality of regions A1 obtained from division along the height of the human body, and the plurality of regions A1 correspond to a plurality of critical anatomical sites, respectively.

In some embodiments, the plurality of regions have the same height, so as to more precisely/accurately divide the critical anatomical sites. Further, the height is determined on the basis of the distribution characteristics of anatomical sites of the human body. For example, according to 8-head and 9-head body proportion principles of the human body, the distribution model includes eight or nine regions A1 having the same height. The 8-head body proportion described above means that the height of the human body is 8 or 9 times the height of the head, and thus the height of each region A1 means the height of one head.

Thus, the positions of different anatomical sites can be defined according to the height of the head. Taking the distribution model 800 determined on the basis of the 8-head body proportion as an example, when the subject to be examined is in the first body orientation, the following may be defined: the position at 0.5 h is the center of the head, where h represents the height of the head, and the positions at 1.5 h, 2 h, 2.5 h, 3.5 h, 4 h, 5 h, and 6 h are the centers of the shoulder, chest, abdomen (or elbow), pelvis, buttocks (or wrist), thigh, and knee, respectively. On the contrary, when the subject to be examined is in the second body orientation, the positions may be defined oppositely, as shown in FIG. 9.

Generally, the height of human bodies (especially adults) satisfies a normal distribution, namely, height ˜N(H, ²), where H is an average height value, and is a standard deviation. Therefore, the positions of critical anatomical sites of the human body also obey a normal distribution. For example, as shown by the plurality of curves in FIG. 6 and FIG. 7, the probability density curves corresponding to different critical anatomical sites are also normally distributed. Specifically, the probability density curve of a critical anatomical site may be determined on the basis of a mathematical operational relationship between the position of the critical anatomical site and the normal distribution of the height. For example, for the center position of the head, it obeys the following distribution: ˜(/8, (/8)²); and for the center position of the shoulder, it obeys the following distribution ˜(3/8, (3/8)²).

Therefore, the type of the radio frequency coupling coil is estimated on the basis of the probability density model and the traveling distance of the scanning table, with high estimation accuracy.

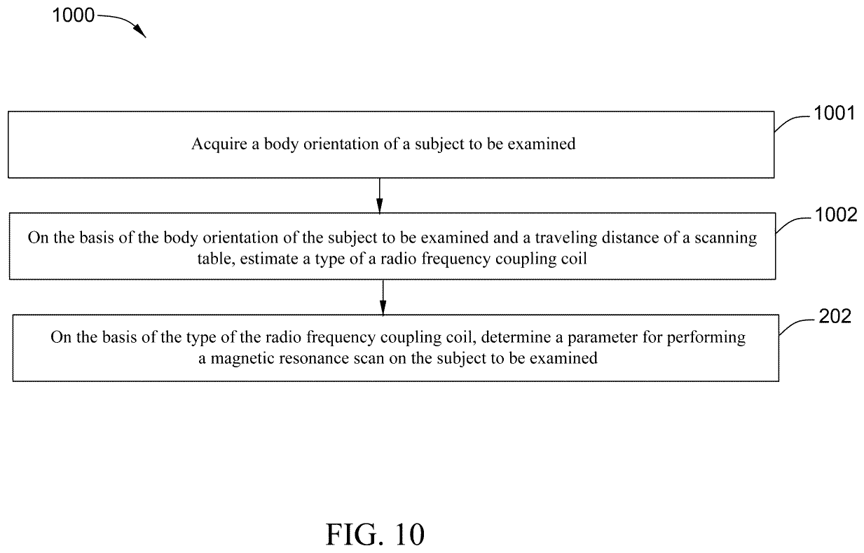

FIG. 10 is a flowchart 1000 of a scanning method for a magnetic resonance system according to some other embodiments of the present application. Specifically, estimating a type of a radio frequency coupling coil may include steps 1001 and 1002. In step 1001, a body orientation of a subject to be examined is acquired. The body orientation may be acquired, for example, on the basis of scanning setting information of the magnetic resonance scan. The scanning setting information described above may be information set by a user in the magnetic resonance system at a preparation stage of the magnetic resonance scan. For example, the scanning setting information may include the body orientation of the subject to be examined (for example, including a first body orientation or a second body orientation), and a site to be scanned/a scan protocol (the scan protocol corresponds to a specific site to be scanned). In the embodiments of the present application, the body orientation of the subject to be examined may be acquired by retrieving the relevant content of the scanning setting information. In step 1002, the type of the radio frequency coupling coil is estimated on the basis of the body orientation of the subject to be examined and a traveling distance of a scanning table. For example, when it is determined in step 1001 that the subject to be examined is in the first body orientation, the type of the radio frequency coupling coil may be estimated by using the corresponding probability density model as shown in FIG. 6, and when it is determined in step 1001 that the subject to be examined is in the second body orientation, the type of the radio frequency coupling coil may be estimated by using the corresponding probability density model as shown in FIG. 7.

In the above embodiment, which site of the subject to be examined is located in a scanning region of the magnetic resonance system is estimated in combination with the body orientation of the subject to be examined and the traveling distance of the scanning table, so that the type of the radio frequency coupling coil can be estimated more accurately.

However, type estimation results in different body orientations may also be acquired by default. The estimation results obtained in this case may not be unique, which may also be confirmed by a user, as will be described below with reference to FIG. 15. In this way, even if the body orientation of the subject to be examined is not acquired, the type of the radio frequency coupling coil can be confirmed, and then a corresponding magnetic resonance scan parameter can be determined.

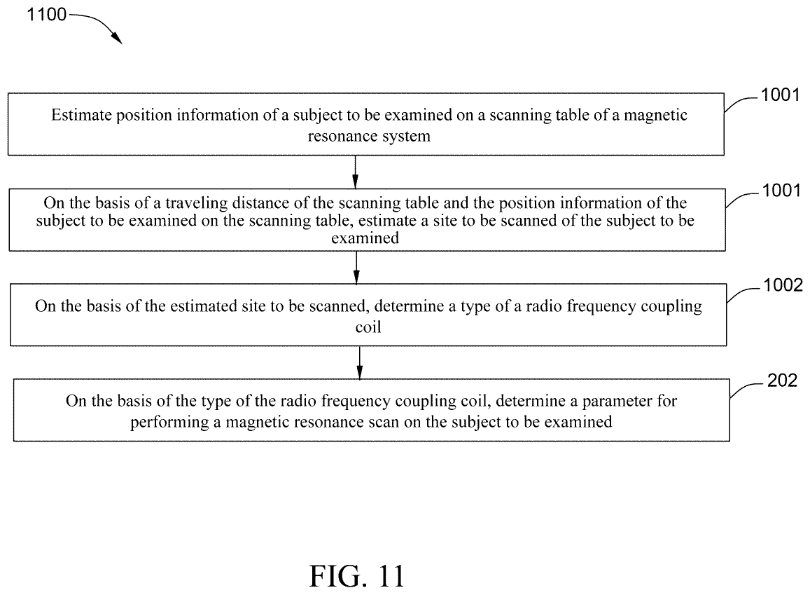

It has been described above that the type of the radio frequency coupling coil is estimated by using the probability density model acquired in advance (which may be optimized in real time). However, in practice, the type of the radio frequency coupling coil may also be estimated on the basis of the physiological information of the subject to be examined acquired in real time, as will be described below with reference to FIG. 11.

FIG. 11 is a flowchart 1100 of a scanning method for a magnetic resonance system according to some other embodiments of the present application. In step 1101, position information of a subject to be examined on a scanning table of the magnetic resonance system is estimated. In step 1102, a site to be scanned of the subject to be examined is estimated on the basis of the above traveling distance of the scanning table and the position information of the subject to be examined on the scanning table. In step 1103, a type of a radio frequency coupling coil is determined on the basis of the estimated site to be scanned. In step 202, a parameter for performing a magnetic resonance scan on the subject to be examined is determined on the basis of the type of the radio frequency coupling coil.

In this way, by acquiring the actual position information of the subject to be examined and combining with the traveling distance of the scanning table, the estimation result is closer to the actual site to be scanned of the current subject to be examined.

Taking the height as an example, when a higher subject to be examined lies on the scanning table, he occupies a longer position range on the scanning table; on the contrary, a shorter subject to be examined occupies a shorter position range. Taking the abdomen as an example, if the position range of the subject to be examined on the scanning table is large, the scanning table travels a long distance to position the abdomen in a scanning region, and if the position range of the subject to be examined on the scanning table is small, the scanning table travels a short distance to position the abdomen in the scanning region. Therefore, by combining the traveling distance of the scanning table and the actual position information of the subject to be examined on the scanning table, it can be more accurately estimated that the site to be scanned located in the scanning interval is the abdomen, and thus the currently used radio frequency coupling coil is estimated as a abdomen coil, thereby reducing the probability of incorrect estimation.

Similarly, the head (or the foot) of the subject to be examined may be guided to be disposed at a fixed position of the scanning table to improve the accuracy of estimation. For example, a head positioning range may be indicated on the scanning table.

In the embodiments of the present application, the position information of the subject to be examined on the scanning table may include position information of a plurality of critical anatomical sites of the subject to be examined on the scanning table, and the site to be scanned estimated in step 1102 may be at least one of the plurality of critical anatomical sites.

For example, in step 1101, a distribution model based on the critical anatomical sites of the subject may be acquired on the basis of the height of the current subject to be examined, and the position information of the critical anatomical sites of the current subject to be examined on the scanning table may be estimated on the basis of the distribution model. The distribution model may be similar to the models shown in FIG. 8 and FIG. 9. Furthermore, on the basis of the traveling distance of the table, it can be estimated which critical anatomical site is positioned in the scanning region of the magnetic resonance system.

Thus, the site to be scanned and the corresponding radio frequency coupling coil are more accurately estimated on the basis of a more precise division of sites.

The above position information of the subject to be examined on the scanning table may be determined not only on the basis of the height, but also estimated on the basis of other features such as gender and age. In other embodiments, a distribution model of critical anatomical sites of the subject to be examined may also be acquired by using techniques such as deep learning and optical photographing, and the position information of each critical anatomical site on the scanning table may be acquired by using the model.

In the embodiments of the present application, when it is known that the subject to be examined is in the first body orientation or the second body orientation, a position range of a plurality of key anatomical portions of the subject to be examined on the scanning table can be estimated in combination with the body orientation. Further, when the traveling range of the scanning table is acquired, the type of the radio frequency coupling coil can be estimated.

Therefore, in the embodiments of the present application, the body orientation of the subject to be examined may also be acquired, and the type of the radio frequency coupling coil may be estimated on the basis of the body orientation and the traveling distance of the scanning table.

However, when the body orientation is not known, corresponding position information may be estimated on the basis of different body orientations, respectively, to obtain a corresponding result to be confirmed by the user from the estimation.

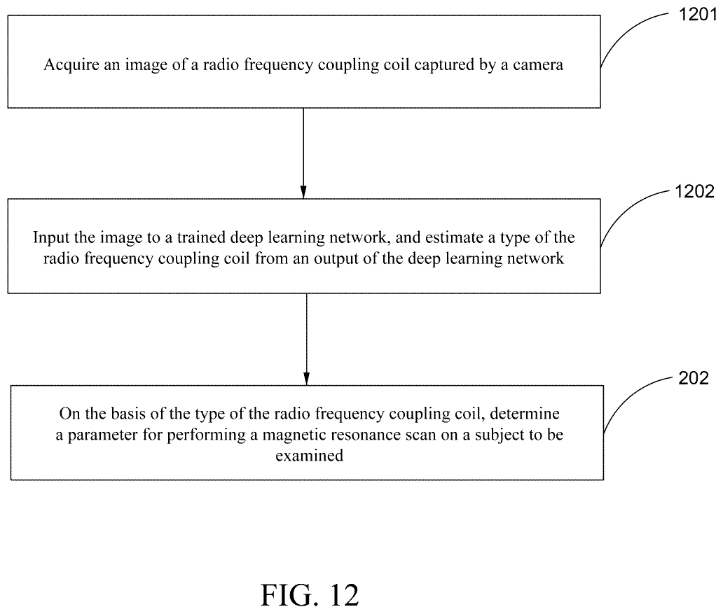

FIG. 12 is a flowchart 1200 of a scanning method for a magnetic resonance system according to some other embodiments of the present application. When an optical camera (for example, the camera 180 shown in FIG. 1) is coupled in the magnetic resonance system, a type of a radio frequency coupling coil may also be automatically identified by using an image of the radio frequency coupling coil captured by the camera. For example, in step 1201, the image of the radio frequency coupling coil captured by the camera is acquired. In step 1202, the image is input into a trained deep learning network, and the type of the radio frequency coupling coil is estimated from an output of the deep learning network. For example, an input data set for training the deep learning network may be an image of the subject to be examined that is captured when a scanning table is at an initial position, the image having the radio frequency coupling coil, and an output data set for training the deep learning network may be the type of the radio frequency coupling coil.

When a magnetic resonance scan is performed on the subject to be examined, two or more of the above different estimation methods for the type of the radio frequency coupling coil may be performed in parallel or sequentially to obtain a plurality of corresponding estimation results, thereby increasing the robustness of the estimation.

As described above, when the estimation result is unique, a parameter of a magnetic resonance scan may be determined on the basis of the unique result. When the estimation result is not unique, one type may be selected by a user from among a plurality of results to determine the parameter of the magnetic resonance scan on the basis of the selected type, which may be implemented through interaction of a user interface.

FIG. 13 is a flowchart 1300 of estimating a type of a radio frequency coupling coil in some embodiments of the present application. A step of acquiring the type of the radio frequency coupling coil may further include steps 1301 and 1302. In step 1301, an estimation result of estimating the type of the radio frequency coupling coil is displayed by means of a user interface. In step 1302, feedback information from a user regarding the estimation result is received by means of the user interface.

For example, one first estimation result may be obtained by using a probability density model acquired in advance and a traveling distance of a scanning table (hereinafter referred to as a first manner). Another first estimation result may also be obtained by using the position information of the current subject to be examined on the scanning table and the traveling distance of the scanning table (hereinafter referred to as a second manner). The type of the radio frequency coupling coil may also be estimated by using an optical image of the radio frequency coupling coil to obtain another first estimation result (hereinafter referred to as a third manner). In the first estimation result, the type of the radio frequency coupling coil includes one type, that is, the type (result) of the estimation is unique. When the first estimation result is obtained by using at least one of the first manner, the second manner, and the third manner, the first estimation result is presented by means of the user interface, and the unique type is confirmed by means of the user interface (that is, the feedback information for the first estimation result includes: confirmation information for the one type).

The type estimated by using the first manner or the second manner may not be unique, and the type estimated by simultaneously performing (for example, performing in parallel or sequentially) at least one of the first manner, the second manner, and the third manner may also not be unique. That is, the estimation result may include a second estimation result, wherein the estimated type of the radio frequency coupling coil includes at least two types. The second estimation result is presented by means of the user interface, and one of the at least two types is selected by means of the user interface. (That is, the feedback information for the second estimation result includes: selection information with respect to the at least two types).

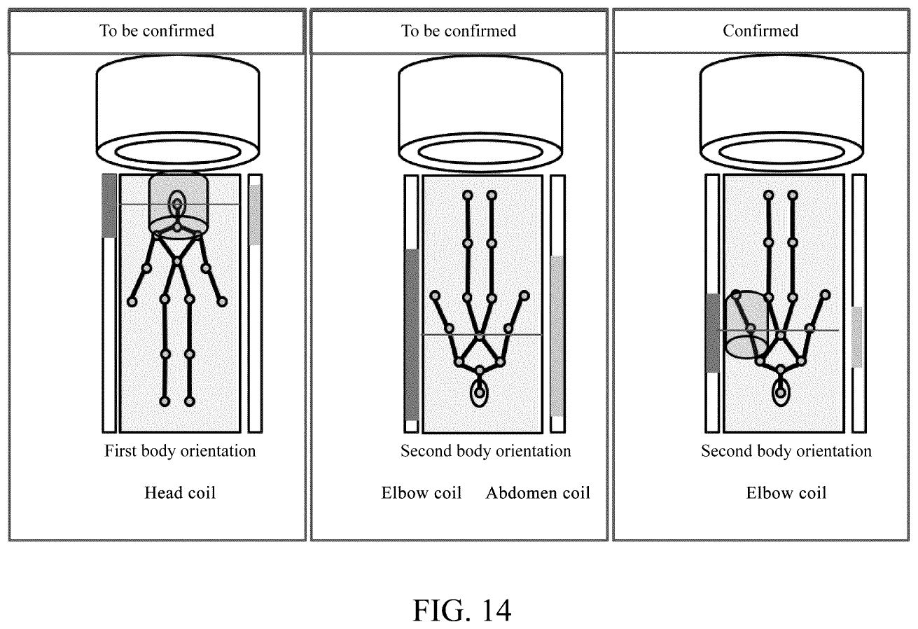

Examples of displaying estimation results by means of the user interface may be shown in FIG. 14. Taking the left diagram of FIG. 14 as an example, when the estimated type is a head coil, the user may select to accept or not accept the estimation result, and when not accepting the estimation result, the user may manually set a coil type. Taking the middle diagram of FIG. 14 as an example, when the estimated type includes elbow and abdomen coils, the user may select one of the estimation results. Taking the right diagram of FIG. 14 as an example, when the user selects an elbow coil, it is displayed that the elbow coil is currently used. Thus, a scanning parameter corresponding to the elbow coil, such as a transmit power suitable for the elbow coil, can be automatically selected or recommended to the user. For example, after a body coil receives the transmit power, the body coil generates a radio frequency pulse. After the radio frequency pulse is amplified by the elbow coil, a sequence of radio frequency excitation pulses are generated, and the sequence of radio frequency excitation pulses have suitable flip angles, so that a radio frequency transmit power corresponding to a required flip angle can be quickly determined therefrom for the current scan.

As described above, when the type of the radio frequency coupling coil is further judged by other means, the type of the radio frequency coupling coil may also be confirmed or selected by the user from the estimation result and the judgment result.

For example, before performing the magnetic resonance scan, the subject to be examined is positioned relative to the scanning table (e.g., in a lying or other posture), and an operator (e.g., a radiologist) determines a site to be scanned on the basis of clinical diagnosis needs and positions a corresponding radio frequency coupling coil relative to the site to be scanned. In some embodiments, the operator may set a site to be scanned determined by him in the magnetic resonance system, and the type of the corresponding radio frequency coupling coil may be automatically judged on the basis of the set site to be scanned. Therefore, the type of the radio frequency coupling coil may be determined on the basis of the estimation result of at least one of the above estimation manners and the above judgment result. For example, these will be described in detail below with reference to FIG. 15.

FIG. 15 is a flowchart 1500 of a scanning method in some embodiments of the present application. In step 1501, a set site to be scanned is determined on the basis of scanning setting information of a magnetic resonance scan. In step 1502, a type of a radio frequency coupling coil is judged on the basis of the set site to be scanned. In step 1503, the type of the radio frequency coupling coil is determined on the basis of a judgment result of judging the type of the radio frequency coupling coil and an estimation result of estimating a type of the radio frequency coupling coil. In step 202, a parameter for performing a magnetic resonance scan on the subject to be examined is determined on the basis of the type of the radio frequency coupling coil.

In step 1503, the judgment result and the estimation result may be displayed by means of a user interface. When the estimation result is consistent with the judgment result, a user may directly confirm the result, and when the estimation result is inconsistent with the judgment result, the user may select one of the results on the basis of an actual type or clinical diagnostic requirements. When there is more than one estimation result but one of them is consistent with the judgment result, the one result being consistent may be selected; and when there is more than one estimation result and each is inconsistent with the judgment result, one of a plurality of estimation results and the judgment result may be selected.

An example of performing a scanning procedure on a subject to be examined will be described below, in which the following steps are included:

Step 1: The subject to be examined is positioned, wherein a radio frequency coupling coil is coupled to a site to be scanned of the subject to be examined.

Step 2: A scanning procedure is started, and a user performs scanning setting by means of a user interface, including setting a scan protocol and a body orientation of a subject to be scanned, the scan protocol including information of a site to be scanned.

Step 3: The site to be scanned is confirmed on the basis of the set scan protocol, and a type of the radio frequency coupling coil is judged on the basis of the site to be scanned.

Step 4: A body orientation is determined on the basis of the above scanning setting, and a corresponding probability density model is selected on the basis of the body orientation.

Step 5: A type of the radio frequency coupling coil is estimated on the basis of the selected probability density model.

Step 6: It is judged whether the judgment result of step 3 is consistent with the estimation result of step 5; if so, a corresponding radio frequency coupling coil and/or its type description are/is displayed, and confirmed by a user; if not, a plurality of corresponding radio frequency coupling coils and/or their type descriptions are displayed and selected by the user therefrom to confirm a type of the radio frequency coupling coil.

Step 7: A parameter for performing a magnetic resonance scan on the subject to be examined is determined on the basis of the confirmed type of the radio frequency coupling coil.

In step 2, the scanning setting may further include the height of the subject to be scanned (the setting may also be input to the magnetic resonance system before the scanning procedure is started), and then in step 5: a distribution model of critical anatomical sites may also be acquired on the basis of the height, and a site to be scanned is estimated on the basis of the distribution model.

In the embodiments of the present application, corresponding scanning parameters may be pre-stored for different types of radio frequency coupling coils, so that when the type of the radio frequency coupling coil is confirmed, a pre-stored scanning parameter may be retrieved to scan the site to be scanned.

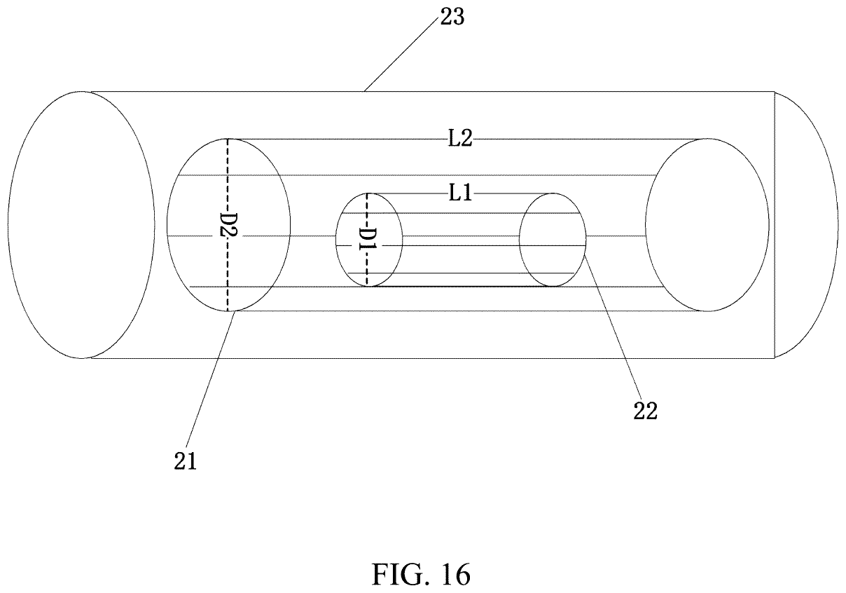

FIG. 16 is a schematic structural diagram of a body coil and a radio frequency coupling coil according to some embodiments of the present application. As shown in FIG. 16, a layer of radio frequency shielding 23 is introduced between the body coil 21 and a gradient coil (not shown). When the body coil 21 is of a birdcage-like structure (a quadrature coil), the radio frequency coupling coil 22 is also of an approximately birdcage-like structure, and an electrical structure thereof constitutes a quadrature coil. When a scan is performed, the radio frequency coupling coil 22 is located within the body coil 21, and is disposed at the site to be scanned of the subject. The volume of the radio frequency coupling coil 22 is smaller than the volume of the body coil 21. For example, the maximum length L1 of the radio frequency coupling coil 22 is smaller than the maximum length L2 of the body coil 21, and the maximum diameter D1 of the radio frequency coupling coil 22 is smaller than the maximum diameter D2 of the body coil 21. In some embodiments of the present application, the radio frequency coupling coil 22 and the body coil 21 have the same electrical structure or electromagnetic structure. An example in which each of the body coil 21 and the radio frequency coupling coil is of a birdcage-like structure is used above, but the embodiments of the present application are not limited thereto. When the body coil 21 has another electrical structure, the radio frequency coupling coil 22 may also correspondingly include a similar electrical structure.

The principles of electromagnetism are employed such that during scanning, the radio frequency coupling coil 22 is close to the body coil 21 so as to generate electromagnetic coupling, which is strong. Therefore, when the body coil 21 transmits a radio frequency pulse, a current may be induced in the radio frequency coupling coil, that is, the radio frequency pulse may be transferred from the body coil 21 to the radio frequency coupling coil 22 by using the induced magnetic field. The radio frequency pulse transferred to the radio frequency coupling coil 22 generates a uniform magnetic field B1, and excites the site to be scanned of the subject to generate resonance, so as to generate a transverse magnetization vector. After the transmission of the radio frequency pulse is completed (after the magnetic field B1 is removed), the transverse magnetization vector attenuates in a spiral shape until the transverse magnetization vector returns to zero. A free induction attenuation signal is generated in the process of attenuation. The free induction attenuation signal can be sensed and received by the radio frequency coupling coil 22 as a magnetic resonance signal. Similarly, when the radio frequency coupling coil 22 receives the magnetic resonance signal, a current may be induced in the body coil 21, that is, the magnetic resonance signal may be transferred from the radio frequency coupling coil 22 to the body coil 21 by using the induced magnetic field, and be transmitted to a receive chain module of the system by means of a transmission cable connected to the body coil 21, and reconstructed into a magnetic resonance image after processing.

Electromagnetic coupling (mutual inductance) is generated between the body coil 21 and the radio frequency coupling coil 22 in a wireless manner to transmit and receive radio frequency signals. Unlike the conventional local coil that needs to be equipped with respective cables, receive channels, and/or transmit chain connection cables for the transmission of magnetic resonance signals, the radio frequency coupling coil does not need to be electrically connected to other structures in the magnetic resonance imaging system. In other words, the radio frequency coupling coil 22 is independent and may implement self-transmission and self-reception of a radio frequency signal without being provided with a cable interface or connected to a scanning table by means of a cable. Therefore, a magnetic resonance scan on a local site of the subject may be implemented using only the receive link and the transmit link of the system connected to the body coil 21 without: providing DC power for switching the transmit/receive modes, disposing a decoupling circuit in the conventional coil array structure, or disposing an additional receive chain module and/or a transmit chain module.

In some embodiments, the radio frequency coupling coil 22 may be designed as a flexible deformable coil, and in a closed state, the radio frequency coil is cylindrical (birdcage-like), and in an open state, the radio frequency coupling coil may be expanded into a rectangular sheet-like structure. When the subject to be examined needs to be scanned, the radio frequency coupling coil is changed to be the open state, so that a site to be imaged of the subject to be examined is placed on the rectangular sheet-like structure of the radio frequency coil, and then the radio frequency coil is changed to be in the closed state, so as to enter the center of the scanning cavity together with the subject to be examined.

In some embodiments, the radio frequency coupling coil 22 includes a three-layer structure, namely, a first mechanical layer, a second mechanical layer, and an electrical layer (a coil layer) forming the birdcage-like structure. The electrical layer is arranged between the first mechanical layer and the second mechanical layer.

In some embodiments, the first mechanical layer and the second mechanical layer are fixedly connected to the electrical layer through thermal engineering, and the electrical layer is enclosed between the first mechanical layer and the second mechanical layer. The first mechanical layer and the second mechanical layer may be made of a flexible insulating material. In the closed state, the radio frequency coupling coil is in a cylindrical shape, the first mechanical layer may also be referred to as an inner layer of the radio frequency coupling coil, and the second mechanical layer may also be referred to as an outer layer of the radio frequency coupling coil. In the open state, a first connecting portion is disposed on one side of the first mechanical layer, and a second connecting portion is disposed on the other side of the second mechanical layer. The first connecting portion and the second connecting portion are connected and fixed to each other, so that the radio frequency coupling coil is changed from the rectangular sheet-like structure to a closed birdcage-like structure. Thus, it is convenient for the subject to be examined to wear the radio-frequency coil.

In some embodiments, at least one groove may further be disposed on the surface of the first mechanical layer. The extension direction of the at least one groove is parallel to a radial direction of the cylindrical tube, and the depth of the at least one groove is less than or equal to the thickness of the first mechanical layer. By means of the at least one groove, the radio frequency coupling coil is more easily bent, and the inner layer is wrinkle-free in the closed state, improving the comfort of the subject to be examined.

In some embodiments, for some specific sites to be scanned, such as the shoulder, the radio frequency coupling coil may include at least two portions connected to each other to adapt to the shape and the body configuration of the site to be scanned of the subject, the at least two portions being connected such that respective electrical structures thereof are connected to form a quadrature coil, thereby forming an electromagnetic structure that is the same or approximately the same as that of the body coil.

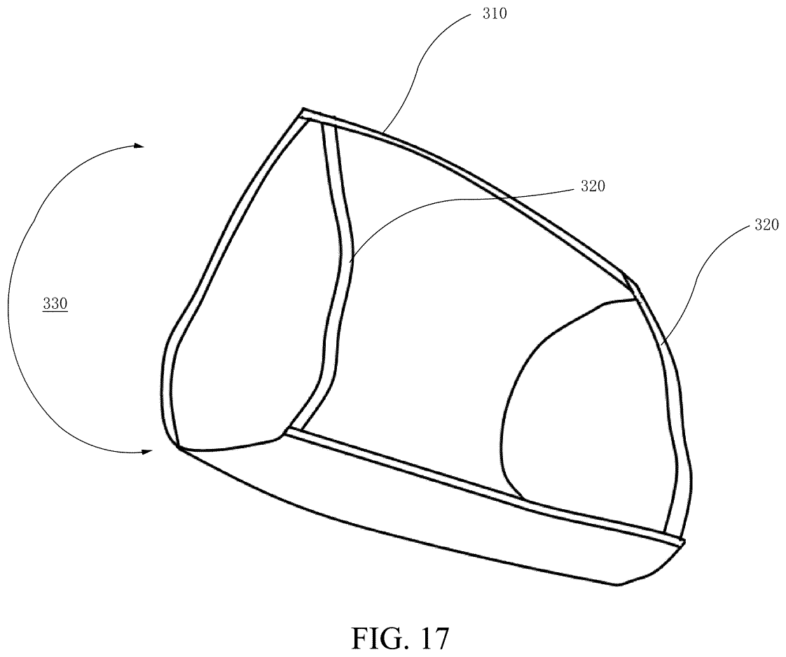

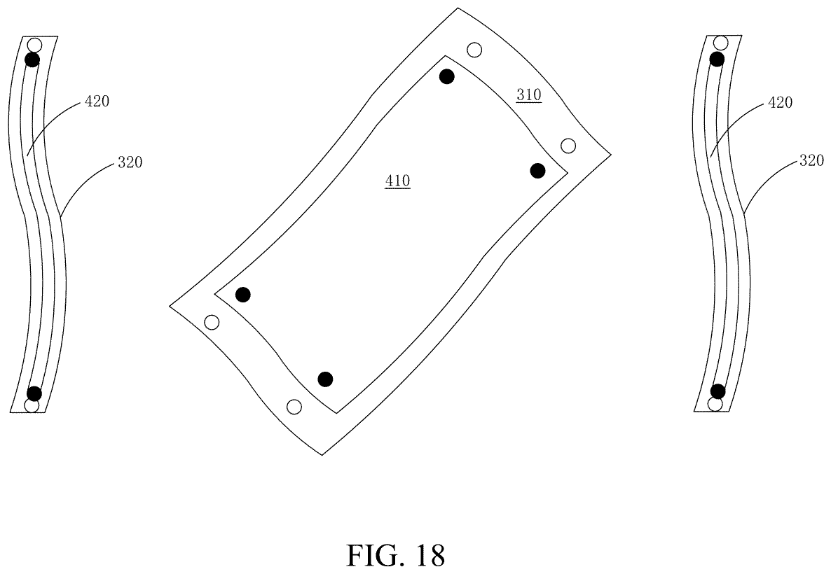

FIG. 17 is a schematic structural diagram of a radio frequency coupling coil according to some other embodiments of the present application. FIG. 18 is a schematic structural diagram of the radio frequency coupling coil of FIG. 17 in an expanded and disassembled state. The radio frequency coupling coil includes a flexible main body portion 310 and an extension portion 320. The flexible main body portion 310 is deformable in a first direction 330 to at least partially surround a site to be scanned of the subject, and the flexible main body portion 310 includes a body coil circuit 410.

The extension portion 320 is connected to the flexible main body portion 310. The extension portion 320 includes a compensation circuit 420, and the compensation circuit 420 is configured to connect to the body coil circuit 410 to form a quadrature coil. The compensation circuit 420 has a resonant frequency that is the same as a radio frequency transmit frequency of the magnetic resonance system.

Those skilled in the art understand that the above “radio frequency transmit frequency of the magnetic resonance system” is a proton precession frequency determined according to a parameter of the magnetic resonance system. For example, the radio frequency transmit frequency (center frequency) is about 63.86 MHz for a 1.5 T magnetic resonance system and about 127.8 MHz for a 3 T magnetic resonance system. Those skilled in the art further understand that the resonant frequency of the compensation circuit 420 may have a specific error from a theoretical proton precession frequency or an actual radio frequency transmit frequency (such an error may be allowed or inevitable), and the present embodiment defines that the resonant frequency of the compensation circuit is the same as the radio frequency transmit frequency of the magnetic resonance system, which includes a case wherein such an error exists.

Electrical parameters of the body coil circuit 410 and the compensation circuit 420 may be set such that the body coil circuit and the compensation circuit have the same resonant frequency. In this case, when the body coil circuit 410 is connected to the compensation circuit 420, the compensation circuit 420 is actually equivalent to being short-circuited with the body coil circuit 410 at the resonant frequency of the magnetic resonance system. Therefore, the compensation circuit 420 does not change the operating frequency of the body coil circuit 410 when it is connected to the body coil circuit.

The above first direction may be a direction in which the flexible main body portion 310 is curled (or bent) and expanded approximately along an arcuate surface (for example, a plane on which an arc line 330 is located). For example, the flexible main body portion 310 may be expanded in a sheet-like shape, and when the radio frequency coupling coil 300 needs to be employed to scan a site to be scanned, one side of the sheet-like flexible main body portion 310 may be curled toward the other side thereof to at least partially surround (or sleeve or wrap) the site to be scanned, or both sides of the sheet-like flexible main body portion may be simultaneously curled toward each other to form a substantially cylindrical space therein to accommodate the site to be scanned.

To adapt to a body configuration of the region to be scanned, such as a shoulder, a space formed by deformation of the flexible main body portion 310 may not be completely closed (or the flexible main body portion 310 may be deformed into an incompletely closed ring), for example, the flexible main body portion may surround only the outside of the shoulder, which may affect a working parameter and performance of the body coil circuit 410 therein. The extension portion 320 can not only serve to fix the flexible main body portion 310 (for example, the extension portion may surround a neck, an axilla, or another body part to prevent the flexible main body portion 310 from disengaging from the shoulder), but also compensate for parameter and performance losses caused by incomplete closure of the flexible main body portion 310, in that the compensation circuit 420 in the extension portion 320 is connected to the body coil circuit to form a quadrature coil.

It is described above that the flexible main body portion 310 and the extension portion 320 are used in cooperation for magnetic resonance imaging of the site to be scanned. However, at least part of the extension portion 320 may be removed from the flexible main body portion 310 such that the flexible main body portion 310 is used as a separate radio frequency coupling coil. For example, for the knee, the wrist, and other parts, the flexible main body portion 310 may be deformed into a closed ring to be sleeved on these parts for magnetic resonance imaging (for example, in the manner shown in FIG. 16). That is to say, at least part of the extension portion 320 is detachably connected to the flexible main body portion 310, and when the at least part of the extension portion 320 is not connected to the flexible main body portion 310, the body coil circuit 410 and the compensation circuit 420 are electrically disconnected.

On the basis of the above description, the embodiments of the present application may further provide a magnetic resonance system, which may include some or all of the components of the magnetic resonance system shown in FIG. 1. For example, the magnetic resonance system of the embodiments of the present application may include a scanning table, a radio frequency body coil, a processor, and the radio frequency coupling coil of the embodiments of the present application. The radio frequency coupling coil is positioned relative to a subject to be examined, wherein when located within the radio frequency body coil, the radio frequency coupling coil is configured to generate electromagnetic coupling with the radio frequency body coil to receive the radio frequency pulse from the radio frequency body coil to generate a radio frequency field for exciting the subject to be examined. The processor is configured to perform the scanning method for the magnetic resonance system according to any of the above embodiments.

In the embodiments of the present application, when imaging is performed by using the radio frequency coupling coil, the scanning parameter may be determined quickly and accurately, thereby improving the scanning efficiency and the image quality.

The above embodiments merely provide illustrative descriptions of the embodiments of the present application. However, the present application is not limited thereto, and suitable variations may be made on the basis of the above embodiments. For example, each of the above embodiments may be used independently, or one or more of the above embodiments may be combined.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A scanning method for a magnetic resonance system, comprising:
acquiring a type of a radio frequency coupling coil; and
on the basis of the type of the radio frequency coupling coil, determining a parameter for performing a magnetic resonance scan on a subject to be examined;
wherein the radio frequency coupling coil is positioned relative to the subject to be examined, and when positioned within a body coil of the magnetic resonance system, the radio frequency coupling coil is configured to generate electromagnetic coupling with the body coil to receive a radio frequency pulse from the body coil, so as to generate a radio frequency field for exciting the subject to be examined.

2. The scanning method according to claim 1, wherein acquiring the type of the radio frequency coupling coil comprises:
on the basis of a traveling distance of a scanning table of the magnetic resonance system from an initial position to a current position, estimating the type of the radio frequency coupling coil.

3. The scanning method according to claim 2, wherein acquiring the type of the radio frequency coupling coil comprises:
on the basis of a probability density model acquired in advance, estimating the type of the radio frequency coupling coil, wherein the probability density model comprises: probability densities of one or more critical anatomical sites serving as sites to be scanned at different traveling distances.

4. The scanning method according to claim 2, wherein acquiring the type of the radio frequency coupling coil comprises:
acquiring a body orientation of the subject to be examined; and
on the basis of the body orientation of the subject to be examined and the traveling distance of the scanning table, estimating the type of the radio frequency coupling coil.

5. The scanning method according to claim 2, wherein acquiring the type of the radio frequency coupling coil comprises:
estimating position information of the subject to be examined on the scanning table of the magnetic resonance system;
on the basis of the traveling distance of the scanning table and the position information of the subject to be examined on the scanning table, estimating a site to be scanned of the subject to be examined; and
on the basis of the estimated site to be scanned, estimating the type of the radio frequency coupling coil.

6. The scanning method according to claim 5, wherein estimating the position information of the subject to be examined on the scanning table of the magnetic resonance system comprises:
on the basis of the height of the subject to be examined, acquiring a distribution model of critical anatomical sites of the subject to be examined; and
on the basis of the distribution model, estimating position information of a plurality of critical anatomical sites of the subject to be examined on the scanning table of the magnetic resonance system;
wherein the estimated site to be scanned is at least one of the plurality of critical anatomical sites.

7. The scanning method according to claim 6, wherein the distribution model comprises a plurality of regions obtained from division along the height of the subject to be examined, and the plurality of regions correspond to the plurality of critical anatomical sites, respectively.

8. The scanning method according to claim 7, wherein the distribution model comprises 8 or 9 regions, and the plurality of regions have the same height.

9. The scanning method according to claim 1, wherein acquiring the type of the radio frequency coupling coil comprises:
acquiring an image of the radio frequency coupling coil captured by a video camera; and
inputting the image to a trained deep learning network, and estimating the type of the radio frequency coupling coil from an output of the deep learning network.

10. The scanning method according to claim 2 further comprising:
displaying, by means of a user interface, an estimation result of estimating the type of the radio frequency coupling coil; and
receiving, by means of the user interface, feedback information from a user regarding the estimation result.

11. The scanning method according to claim 10, wherein the estimation result comprises a first estimation result, wherein the estimated type of the radio frequency coupling coil comprises one type, and the feedback information comprises: confirmation information for the one type.

12. The scanning method according to claim 10, wherein the estimation result comprises a second estimation result, wherein the estimated type of the radio frequency coupling coil comprises at least two types, and the feedback information comprises: selection information with respect to the at least two types.

13. The scanning method according to claim 2, wherein acquiring the type of the radio frequency coupling coil comprises:
on the basis of scanning setting information of the magnetic resonance scan, determining a set site to be scanned;
on the basis of the set site to be scanned, judging a type of the radio frequency coupling coil; and
on the basis of a judgment result of judging the type of the radio frequency coupling coil and an estimation result of estimating the type of the radio frequency coupling coil, determining the type of the radio frequency coupling coil.

14. The scanning method according to claim 13, wherein acquiring the type of the radio frequency coupling coil comprises:
displaying, by means of a user interface, the judgment result and the estimation result; and
receiving, by means of the user interface, confirmation information or selection information among the judgment result and the estimation result.

15. The scanning method according to claim 1, wherein
the parameter comprises a radio frequency gain used when pre-scanning is performed on the subject to be examined.

16. The scanning method according to claim 1, wherein determining the parameter for performing the magnetic resonance scan on the subject to be examined comprises:
retrieving, from pre-stored parameters, a parameter corresponding to the type of the radio frequency coupling coil for the magnetic resonance scan.

17. A magnetic resonance system, comprising:
a scanning table, configured to carry a subject to be examined;
a radio frequency body coil, configured to output a radio frequency pulse;
a radio frequency coupling coil, positioned relative to the subject to be examined, and when located within the radio frequency body coil, the radio frequency coupling coil is configured to generate electromagnetic coupling with the radio frequency body coil to receive the radio frequency pulse from the radio frequency body coil, so as to generate a radio frequency field for exciting the subject to be examined; and
a processor, configured to perform the scanning method for the magnetic resonance system according to claim 1.
